(19) United States
(12) Patent Application Publication
(10) Pub. No.: US 2009/0238664 A1
(43) Pub. Date: Sep. 24, 2009

(54) STORING APPARATUS AND TRANSPORTING SYSTEM WITH STORAGE

(75) Inventors: Masanao MURATA, Ise-shi (JP); Takashi YAMAJI, Ise-shi (JP); Teruya YAMAJI, Ise-shi (JP)

Correspondence Address: YOUNG & THOMPSON, 209 Madison Street, Suite 500, ALEXANDRIA, VA, 22314, US

(73) Assignee: ASYST TECHNOLOGIES JAPAN, INC., ISE-SHI (JP)

(21) Appl. No.: 12/361,556

(22) Filed: Jan. 29, 2009

(30) Foreign Application Priority Data
Mar. 24, 2008 (JP) 2008-075430

(51) Int. Cl. H01L 21/67; H01L 21/677

(52) U.S. Cl. 414/222.02; 414/222.07

(57) ABSTRACT

Each storage provided for an storing apparatus is provided with: a driving device capable of reciprocating the load in a horizontal one direction and in a vertical direction; and a rack having a plurality of rack portions at a plurality of stages in the vertical direction, each stage including one or a plurality of rack portions in the horizontal one direction, the rack portion capable of accommodating or putting thereon the load to be displaced by the driving device. The storing apparatus is provided with a plurality of controllers, which control the loading and unloading in respective groups, each group comprising at least one or a plurality of storages of the plurality of the storages, and which can perform complementary control with each other.

### BACKGROUND OF THE INVENTION

1. Field of the Invention

The present invention relates to a storage such as a stocker for temporarily storing a load (i.e., a transported object or an object), such as a FOUP (Front Opening Unified Pod) for accommodating or housing various substrates for manufacturing semiconductor elements and the like, at the position located close to a track, in a traveling system for transporting the load on the track; a storage set constructed by combining a plurality of such storages; a storing apparatus in which particularly such a storage set is installed along the track; and a transporting system with the storage, equipped with such a storing apparatus. Here, the “load” (i.e., the “transported object” or “object”) in the present invention means a product, an intermediate product, a part, an article, a work, a partly-finished good, a good or the like (e.g, a semiconductor or LCD device), or means a box or container for containing such a product or the like (e.g, a container containing the semiconductor or LCD device), which has been transported or is to be transported by the transporting carriage. The load may be a carrier for containing an object to be carried such as a FOUP.

2. Description of the Related Art

This kind of storage is installed close to a track on which a transporting carriage such as a vehicle travels, for example. In the storage, many rack portions are installed so as to store many loads which are transported or to be transported by the transporting carriage. Further, an in-storage transporting apparatus, which is called as a “stacker robot”, a “stacker crane” or the like, is provided to perform the transportation of the load between a “port” and the assigned or designated rack portion (i.e., to perform transportation within the storage). The “port” is to perform the delivery-and-receipt or the taking-out and putting-in of the load (i.e., loading and unloading of the load) between the inside of such a storage and the transporting carriage. Especially, the transportation within the storage including many rack portions arranged crisscross is made possible by the stacker robot or the like. For example, large storages, which allow loading, unloading, and storage of many loads such as several ten to several hundred loads and which weigh several ton to dozen tons, have been also put in practical use (refer to Japanese Patent Application Publication Laying Open No. 2006-049454 and 2003-182815).

However, according to the large storage in each of the above described related arts NO. 2006-049454 and 2003-182815, the control and structure of the in-storage transporting apparatus such as a stacker robot or the like are basically complicated and highly sophisticated, and thus the in-storage transporting apparatus is high-cost. As for the control thereof, the complicated, highly sophisticated, and high-cost control is required using a controlling apparatus with a high processing capability.

In contrast to the large storage, a small storage has been suggested by the present inventors, which is provided only with a small number of rack portions of ten percent of those of a general storage used for semiconductor manufacturing. Such a small storage can be provided relatively inexpensively because of the less number of rack portions; however, it is high-cost to use the aforementioned controlling apparatus for the control of this one small storage. It is thus attempted to use one controlling apparatus to control a plurality of stockers; however, if the controlling apparatus breaks down or goes out of order, for example, the loading and unloading operation by all the stacker robots can be no longer performed and at least one portion of the transporting system is stopped, which is a technical problem.

It is therefore an object of the present invention to provide a storage, which allows efficient loading and unloading of a load by use of a relatively simple structure and which can increase the reliability and maintain the high capacity utilization; a storage set constructed by combining a plurality of such storages; a storing apparatus in which particularly such a storage set is installed along the track; and a transporting system with the storage, equipped with such a storing apparatus.

### SUMMARY OF THE INVENTION

The above object of the present invention can be achieved by a storing apparatus provided with a storage set installed along a track, the storage set being constructed by combining a plurality of storages in each of which loading and unloading of a load is performed with a transporting carriage for transporting the load on the track, each of the plurality of storages provided with: a driving device capable of reciprocating the load in a horizontal one direction and in a vertical direction; and a rack having a plurality of rack portions at a plurality of stages in the vertical direction, each stage including one or a plurality of rack portions in the horizontal one direction, the rack portion capable of accommodating or putting thereon the load to be displaced by the driving device, the storing apparatus provided with a plurality of controllers, which control the loading and unloading in respective groups, each group provided with at least one or a plurality of storages of the plurality of the storages, and which can perform complementary control with each other.

According to the storing apparatus of the present invention, in the loading, if the load is transferred from the transporting carriage to the port for loading and unloading the individual storage, which constitutes the storage set, the load is moved to the desired rack portion by the driving device, which is provided with the vertical driving portion and the horizontal driving portion. In other words, in-storage transportation is performed. In the unloading, the load is in-storage transported by the driving device from the desired rack portion. Then, if the load is moved to the port of the storage set, the transfer to the transporting carriage is performed.

In the present invention, in particular, the rack has the plurality of rack portions at the plurality of stages in the vertical direction, each stage including the one and the plurality of rack portions in the horizontal one direction. The driving device can reciprocate the load in the horizontal one direction and in the vertical direction, in association with the rack. Therefore, the two-axis motion in the vertical direction and the horizontal one direction allow the in-storage transportation of the load from the port for loading and unloading (or another rack portion) to the desired one of the rack portions. Alternatively, the two-axis motion in the vertical direction and the horizontal one direction allows the in-storage transportation of the load from the desired one of rack portions to the port for loading and unloading (or another rack portion).

As for the individual storage, for example, the entire bone structure of is constructed such that the rack has a thin, plane-like shape, such as having m stages (wherein m is a natural number of 2 or more) in the vertical direction, n lines (wherein n is a natural number of 1 or more) in the horizontal direction, and only one line in the remaining horizontal one direction perpendicular thereto (hereinafter, simply referred to as a “thickness direction”).

According to the present invention, however, the storing apparatus is provided with the plurality of controllers, and each controller controls the loading and unloading of the load in each group, which is provided with the one or the plurality of groups. Specifically, each controller transmits an instruction signal to load or unload the predetermined number of loads in predetermined time with a predetermined transporting carriage, for example, to a sequencer built in the driving device in the individual storage. The sequencer that has received the instruction signal controls the driving device and allows the loading and unloading based on the instruction signal with the predetermined transporting carriage. By controlling the loading and unloading with the transporting carriage in the individual storage in each group, for example, a load stock status is managed in each group, or a rack status (i.e. whether or not the load is put) is managed. Specifically, for example, an integrated management system transmits instruction signals which indicate the identification number of the load to be unloaded and the entrance of the storage on which the load is put, to the controller provided with the storage. The controller that has received the instruction signals controls the driving device to transport the load with the ID from the rack on which the load is put to the entrance.

In particular, each controller is adapted to perform mutual complementary control in the case of a failure or abnormality, while performing such distributed control in the normal time. Here, the “complementary control” denotes that even if one of the plurality of controllers can no longer operate, another controller controls the group that is supposed to be controlled by the one controller. In other words, it means that another controller complements the one controller and performs the control. Therefore, for example, when one controller is down because of the failure, abnormality, or the like, if relatively simple control change, such as changing a control line, allows the group that has been controlled by the down controller to be controlled by another normal controller, then a reduction in the capacity utilization of the transporting system can be prevented at a minimum or closer level. Incidentally, the complementary control may be control or management identical to the original control. Alternatively, it may be more or less inferior to the original control, in terms of the processing time, control content, or the like, as provisional control until the broken controller is repaired.

For example, the plurality of controllers make pairs in advance. In the case of the failure, abnormality, or the like of one controller, the other paired controller of the one controller may perform the complementary control, instead of the one controller. Alternatively, for example, the plurality of controllers are classified into a plurality of groups in advance, and in the case of the failure, abnormality, or the like of one controller, another controller of the one or the plurality of controllers which are classified in the same group as that of the one controller may perform the complementary control, instead of the one controller. Alternatively, in the case of the failure, abnormality, or the like of one controller, any of the remaining controllers that is in the status or condition suitable for the complementary control is selected, and the selected controller may perform the complementary control, instead of the one controller.

Therefore, if the individual controllers have processing abilities extra enough to perform the complementary control in the failure or the like of one controller, the individual controllers can perform the complementary control in the storing apparatus. This is extremely useful from the viewpoint of efficient utilization of the processing abilities or from the economic viewpoint, compared to if the plurality of controllers are redundantly provided in each group.

In addition, according to the present invention, it is possible to combine the number of storages that matches the gap between various apparatuses or the like in the direction along the track installed in a factory, which is extremely useful in practice. In other words, regardless of how the gap is designed between the apparatuses installed along the track, the design can be sufficiently within an allowance if the storage set of the present invention is used. Moreover, the in-storage transportation in the individual storage is extremely efficiently performed by the two-axis motion which thinly extends in the thickness direction as described above, i.e. the two-axis motion with respect to the rack having the plurality of rack portions located at each stage throughout the plurality of stages. Incidentally, the plurality of storages which constitute the storage set may be disposed separately in two gaps which sandwich the apparatus therebetween.

As described above, the storage set can be disposed in the condition that the predetermined number of storages is combined, in a relatively small gap or relatively large gap along the track of the transporting carriage. In particular, by using the plurality of controllers to perform the distributed control and to allow the complementary control, it is possible to efficiently use a hardware resource and improve economic efficiency while maintaining the high capacity utilization of the storing apparatus including the storage set or the transporting system as a whole.

In one aspect of the storing apparatus of the present invention, it is further provided with a changing device for changing a control path by the plurality of controllers to a control path for complementary control.

According to this aspect, for example, each controller and its control target, i.e. the driving device, are connected by the control path, such as a wired or wireless control cable or control line. In the failure or the like, the changing device such as a changeover switch for changing the cable or line changes the control path by the plurality of controllers to the control path for complementary control. Thus, even if one controller can no longer operate, the changing device allows the complementary control to be started extremely quickly, so it is extremely useful in increasing the capacity utilization of the storing apparatus or the transporting system as a whole. Incidentally, the changing device may be manually changed by a system administrator in a trial run, emergency, or the like.

In this aspect, if a failure or abnormality is detected in one of the plurality of controllers, the changing device may perform the changing such that the complementary control of the one controller is performed by another of the plurality of controllers.

By virtue of such construction, for example, by the controllers' mutual monitoring of the failure or abnormality or by a monitoring device exclusive to monitor the failure or the like of the individual controller, the failure or the like of one of the plurality of controllers is detected. If the failure or the like is detected in this manner, the changing device allows another of the plurality of controllers to perform the complementary control of the one controller related to the failure or the like. Thus, even if one controller can no longer operate, it is possible to start the complementary control by the changing device, extremely quickly, and it is further useful in increasing the capacity utilization of the storing apparatus or the transporting system as a whole.

Incidentally, a user or operator who detects the failure or the like may manually or semi-manually perform the changing operation of changing to the complementary control.

In another aspect of the storing apparatus of the present invention, the driving device comprises: a putting portion having a first putting surface which can support the load from a bottom side of the load; a horizontal driving portion capable of reciprocating the putting portion in the horizontal one direction; and a vertical driving portion capable of reciprocating the putting portion in the vertical direction, and the rack has second putting surfaces as the rack portions, one or a plurality of second putting surfaces being disposed at horizontal positions to which the horizontal driving portion can access, each second putting surface capable of transferring the load with the first putting surface.

According to this aspect, the operation of the driving device is the two-axis motion in which the driving device reciprocates in the horizontal one direction and the vertical direction in the thin storage. Thus, the control is much easier than when a stacker robot or the like is controlled. By such a driving device, in the loading, for example, the load is transferred from the transporting carriage onto the second putting surface which functions as the port for loading and unloading. Then, the load, transferred on the second putting surface which functions as the port, is put onto the first putting surface of the putting portion which can move in the two-axis directions. For example, the first and second putting surfaces are constructed to support mutually different portions on the bottom surface of the load (typically, a central-side portion and a peripheral-side portion), and either one can support the load. When the putting portion is moved to the horizontal position and vertical position at which the second putting surface which functions as the port exists, the load is supported on the first putting surface instead of the second putting surface which functions as the port, by which the transfer is performed from the second putting surface to the first putting surface. Typically, the first putting surface is moved by the vertical driving portion until it is above the second putting surface, by which the load is supported by the first putting surface. By this, the in-storage transportation in the loading is started. Here, the simple two-axis operation by the vertical driving portion and the horizontal driving portion allows the quick in-storage transportation to any of the second putting surfaces in the rack.

Then, when the putting portion is moved to the horizontal position and vertical position at which the second putting surface to be used for storage exists, the load is supported on the second putting surface instead of the first putting surface, by which the transfer is performed from the first putting surface to the second putting surface. Typically, the first putting surface is moved by the vertical driving portion until it is below the second putting surface, by which the load is supported by the second putting surface. By this, the in-storage transportation in the loading is ended, and the storage in the rack is started.

On the other hand, in the unloading, the putting portion is moved to the vertical position and horizontal position at which the second putting surface on which the load to be unloaded is put exists. Then, the load is supported on the first putting surface instead of the second putting surface, by which the transfer is performed from the second putting surface to the first putting surface. Typically, the first putting surface is moved by the vertical driving portion until it is above the second putting surface, by which the load is supported by the first putting surface. By this, the in-storage transportation in the unloading is started. Then, the putting portion is moved to the vertical position and horizontal position at which the second putting surface which functions as the port exists. Here, the simple two-axis operation by the vertical driving portion and the horizontal driving portion allows the quick in-storage transportation from any of the second putting surfaces in the rack.

Then, the load is supported on the second putting surface which functions as the port instead of the first putting surface, by which the transfer is performed from the first putting surface to the second putting surface which functions as the port. Typically, the first putting surface is moved by the vertical driving portion until it is below the second putting surface, by which the load is supported by the second putting surface. By this, the in-storage transportation in the unloading is ended, and the transfer from the port to the transporting carriage is ready.

Then, the transporting carriage which has been already waiting at a position on the track facing the port for loading and unloading or which will reach to this position next allows the transfer from the port to the transporting carriage.

Consequently, the relatively simple structure, i.e. the putting portion which is moved in the two-axis direction by the driving device, and the simple control allow the in-storage transportation. Moreover, the in-storage transportation by the driving device can be performed while the transfer is performed between the transporting carriage and the port. That also dramatically improves the transportation efficiency in the storage.

The above object of the present invention can be achieved by a transporting system with a storage, provided with: the aforementioned storing apparatus of the present invention (including its various aspects); the track; and the transporting carriage.

According to the transporting system with the storage of the present invention, since it has the aforementioned storing apparatus of the present invention, in which the plurality of controllers are used to perform the distributed control and to allow the complementary control. Thus, it is possible to efficiently use a hardware resource and improve economic efficiency while maintaining the high capacity utilization of the storing apparatus including the storage set or the transporting system as a whole.

The nature, utility, and further features of this invention will be more clearly apparent from the following detailed description with reference to preferred embodiment of the invention when read in conjunction with the accompanying drawings briefly described below.

### BRIEF DESCRIPTION OF THE DRAWINGS

FIG. 1 is a perspective view showing the appearance of a transporting system provided with a storage in a first embodiment;

FIG. 2 is a cross sectional view showing the internal structure of the storage in the first embodiment;

FIG. 3A is a cross sectional view showing an engaging condition of first and second putting surfaces in the first embodiment;

FIG. 3B is a cross sectional view showing an engaging condition of first and second putting surfaces in the first embodiment;

FIG. 4A is a plan view showing an operational condition in horizontal one direction of a putting portion in the first embodiment.

FIG. 4B is a plan view showing an operational condition in horizontal one direction of the putting portion in the first embodiment.

FIG. 5 is a plan view showing a practical arrangement condition of the storage in the first embodiment;

FIG. 6 is a perspective view showing the appearance of a transporting system including a storage set in a second embodiment;

FIG. 7 is a functional block diagram showing the structure of a transporting system in a third embodiment; and

FIG. 8 is a flowchart showing the complementary control process of the transporting system in the third embodiment.

### DETAILED DESCRIPTION OF THE PREFERRED EMBODIMENTS

Hereinafter, the embodiments of the present invention will be explained with reference to the drawings.

### First Embodiment

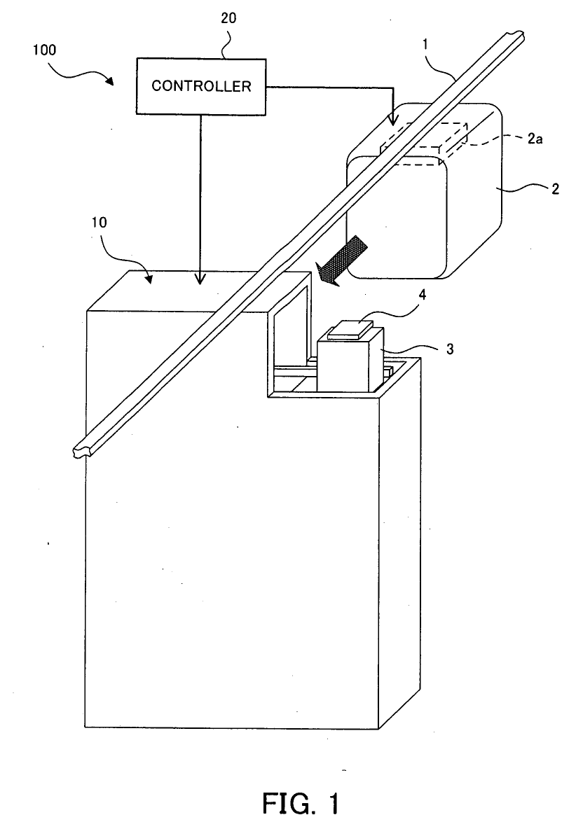

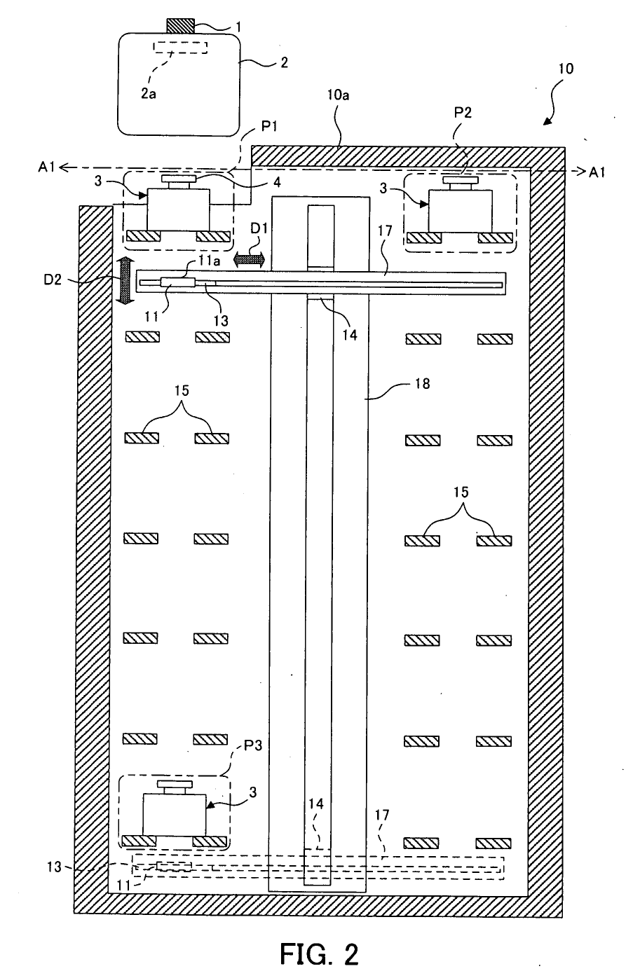

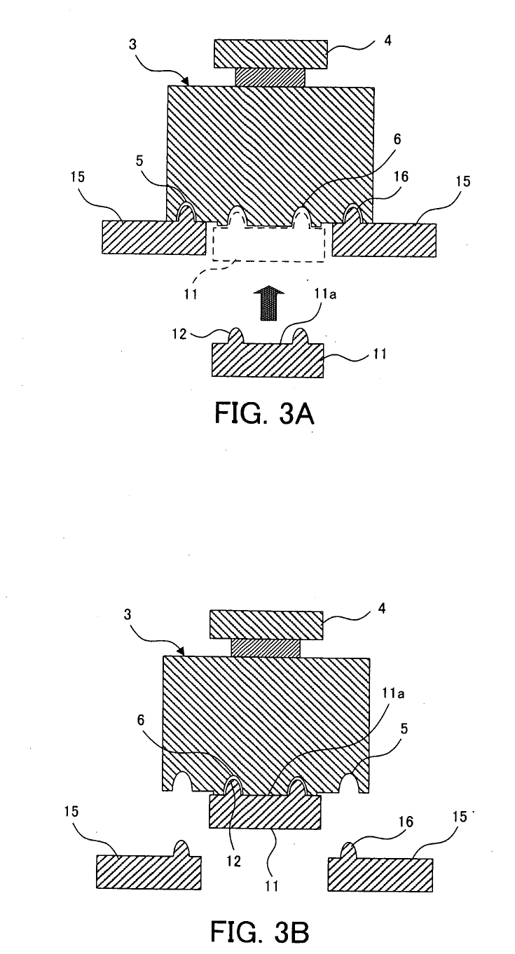

Firstly, the structure of a storage in a first embodiment will be explained with reference to FIG. 1 to FIG. 3B. FIG. 1 is a perspective view showing the appearance of a transporting system provided with the storage in the first embodiment. FIG. 2 is a cross sectional view showing the internal structure of the storage in the first embodiment. FIG. 3A and FIG. 3B are cross sectional views showing engaging conditions of first and second putting surfaces in the first embodiment with respect to a load.

In FIG. 1, a transporting system 100 is provided with a rail 1, a transporting carriage 2, a stocker 10 (which is one example of the “storage” of the present invention), and a controller 20. The transporting system 100 drives the transporting carriage 2, and then transports a FOUP 3 on the rail 1. The rail 1, which is an example of the “track” of the present invention, functions as a track for the transporting carriage 2 to travel thereon.

The transporting carriage 2 is the OHT (Overhead Hoist Transport) driven by, for example, a linear motor and transports the FOUP 3 to the stocker 10, a not-illustrated manufacturing apparatus, OHT buffer, large scale stocker, and the like. The transporting carriage 2 includes therein a hoist 2a which moves in the vertical direction.

Upon transporting, the hoist 2a holds a flange 4 of the FOUP 3 which is to be transported, by a holding mechanism for example. The hoist 2a is constructed to be able to move up and down in the vertical direction below the rail 1 by a hoisting mechanism such as a take-up belt and a take-down belt. Upon loading or unloading the FOUP 3 with the stocker 10, the hoist 2a moves to the position above a port for loading and unloading of the stocker 10. At the position where the hoist 2a moves down to the port, the hoist 2a holds or releases the flange 4. At this position, the bottom surface of the FOUP 3 contacts with the second putting surface (i.e., the floor surface of the port) described later.

As shown in FIG. 1 and FIG. 2, the FOUP 3, which is an example of the “load” of the present invention, is transported in the stocker 10 (i.e., is transported in the storage) for unloading and loading with respect to the transporting carriage 2 and for the adjustment of the storing position and so on.

As shown in FIG. 3A and FIG. 3B, the FOUP 3 has concave parts 5 and 6 on the bottom surface. The concave part 5 is formed to have the size corresponding to a convex part 16 placed in a rack 15 described later. On the other hand, the concave part 6 is formed to have the size corresponding to a convex part 12 placed in a putting portion 11 described later.

In FIG. 1 again, on the basis of the process schedule of a semiconductor device manufacturing for example, the controller 20 orders the transporting carriage 2 and the stocker 10 to transport, load, and unload (which includes in-storage transporting) the FOUP 3. In response to this order, the transporting carriage 2 and the stocker 10 are driven, the FOUP 3 is transported by the transporting carriage 2, and various processes are performed on the transported FOUP 3, by which the semiconductor device is manufactured.

### (Single Storage)

The stocker 10, as one example of the “storage” of the present invention, is installed adjacent to the rail 1 and stores a plurality of FOUPs 3.

In FIG. 2, the stocker 10 has: an in-storage transporting apparatus 19 including a putting portion 11, a horizontal driving portion 13, and a vertical driving portion 14; and a plurality of racks 15. The in-storage transporting apparatus 19, as one example of the “driving portion” of the present invention, is provided with a not-illustrated robot controller. The robot controller responds to the order or instruction from a controller 20 and drives each device or portion of the in-storage transporting apparatus 19, to thereby transfer the FOUP 3 among the racks 15. By this transferring, the FOUP 3 is put on the intended rack (i.e. a rack for storing or keeping) among the racks 15. Thus the FOUP 3 is stored in the stocker 10. Alternatively, as described later in detail, the FOUP 3 is transferred to a rack 15 which functions as a port for loading and unloading.

In order to transfer the FOUP 3 among the racks 15, the putting portion 11 is moved in the horizontal one direction by the horizontal driving portion 13, and is moved in the vertical direction by the vertical driving portion 14. The putting portion 11 has a first putting surface 11a at the top surface thereof. In the transfer, the first putting surface 11a contacts with the bottom surface of the FOUP 3 and supports the FOUP 3 from its bottom side. On the first putting surface 11a, the convex part 12 is formed as a supporting component. As shown in FIG. 3B, the convex part 12 is formed to have the size corresponding to the concave part 6 of the FOUP 3. In the transfer, the convex part 12 is engaged to this concave part 6.

In FIG. 2 again, the horizontal driving portion 13 is driven on a horizontal guide 17 which extends in the horizontal one direction by a not-illustrated motor for example. The horizontal driving portion 13 is connected with the putting portion 11 and reciprocates the putting portion 11 along the horizontal guide 17 in a horizontal one direction D1.

The vertical driving portion 14 is driven on a vertical guide 18 which extends in the vertical direction by a not-illustrated motor for example. To the vertical driving portion 14, the center portion of the horizontal guide 17 is fixed. The vertical driving portion 14 reciprocates the horizontal guide 17 along the vertical guide 18 in a vertical direction D2. In the reciprocation, the putting portion 11 is located at the center portion of the horizontal guide 17. In this manner, the putting portion 11 is moved in two-axis directions of the vertical direction and the horizontal one direction by the horizontal driving portion 13 and the vertical driving portion 14.

The racks 15 are provided with 14 racks in total of 7 stages in the vertical direction, 2 lines in the horizontal one direction, and 1 line in the thickness direction. The putting portion 11 moves among the 14 racks 15, by which the FOUP 3 is transferred. Each rack 15 has a second putting surface 15a on the top surface thereof. On this second putting surface 15a, the FOUP 3 is put. On the second putting surface 15a, a convex part 16 is formed as a supporting component. As shown in FIG. 3A, the convex part 16 is formed to have the size corresponding to the concave part 5 of the FOUP 3. In putting (as well as storing or keeping) the FOUP 3, the convex part 16 is engaged to this concave part 5.

In FIG. 2 again, one of the 14 racks 15 (in other words, the second putting surface 15a which the one rack 15 has) functions as the port for loading and unloading, to deliver and receive (or transfer) the FOUP 3 with the transporting carriage 2. The rack 15, which is set as a port, is one of the two racks existing on the top stage (i.e., one rack 15 located in an area P1 shown by a two dot chain line in FIG. 2). The main unit 10a of the stocker 10, located above and on the lateral side of this one rack 15, is opened so that the FOUP 3 can be loaded and unloaded therethrough.

Incidentally, not only the one rack 15 set as a port, but also the putting portion 11 moved to the area P1 may function as an additional port. Alternatively, the putting portion 11 may function as the sole port instead of the one rack 15. In this case, if the putting portion 11 on which the FOUP 3 is not put is disposed in the area P1 without the rack 15 disposed in the area P1, the FOUP 3 is directly loaded from the transporting carriage 2 to the putting portion 11. Alternatively, if the putting portion 11 on which the FOUP 3 is put is disposed in the area P1, the FOUP 3 is directly unloaded to the transporting carriage 2 from the putting portion 11.

As for the arrangement of the stocker 10, the rack 15 set as a port is placed below the rail 1. Specifically, the azimuth of the horizontal one direction in which the putting portion 11 is moved perpendicularly intersects the azimuth of the rail 1.

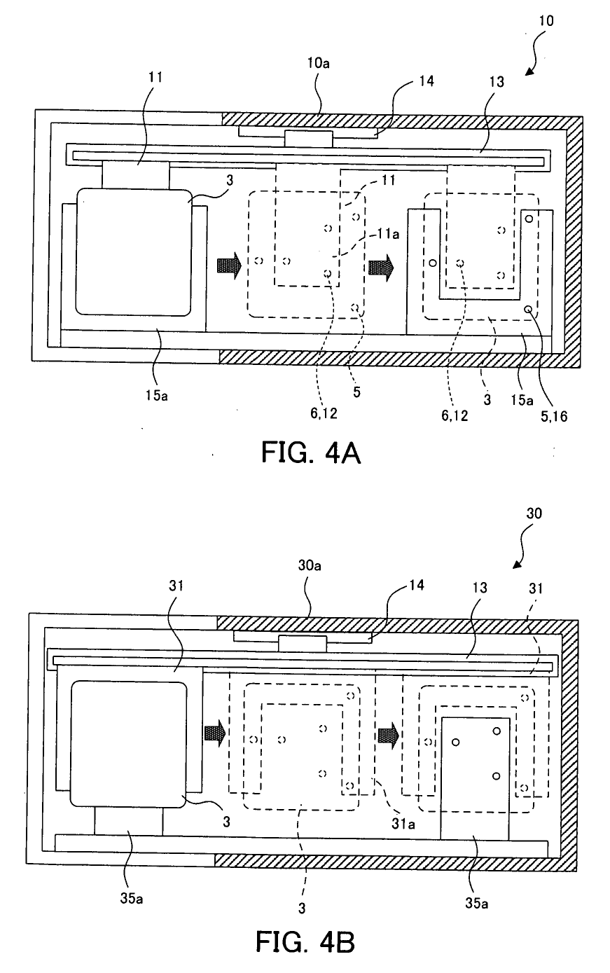

Next, with reference to FIG. 4A, the figure of the first and second putting surfaces related to this embodiment will be explained. Here, FIG. 4A is a plan view showing an operational condition in the horizontal one direction of the putting portion in this embodiment. Specifically, FIG. 4A corresponds to the A1-A1 cross section in FIG. 2 and shows two lines of the racks 15 (i.e. the second putting surface 15a) set at the top stage of the stocker 10.

As shown in FIG. 4A, when viewed from the top surface side of the stocker 10, the second putting surface 15a is formed into a U character like a horseshoe, and the first putting surface 11a is formed into a square like an island to occupy the center of the U character. Therefore the first putting surface 11a and the second putting surfaces 15a have respectively a flat shape complemented by each other. Between the first putting surface 11a and the second putting surfaces 15a, the FOUP 3 is transferred.

Incidentally, in the example shown in FIG. 3A and FIG. 3B as well as FIG. 4A, when viewed in a planar manner, the first putting surface 11a lies inside the second putting surface 15a and has a smaller external diameter than the second putting surface 15a. However, conversely, the first putting surface 11a and the second putting surface 15a may be constructed such that the first putting surface 11a lies outside the second putting surface 15a and has a larger external diameter than the second putting surface 15a. In this case, as a modified example of the figures of the first putting surface 11a and the second putting surface 15a shown in FIG. 4A, as shown in FIG. 4B for example, when viewed from the top surface side of the stocker 30, the first putting surface 31a is formed into a U character like a horseshoe, and the second putting surface 35a is formed into a square like an island to occupy the center of the U character. As described above, the stability in the in-storage transportation with the FOUP 3 put on the putting portion 31 is increased when the first putting surface 31a moved from side to side or up and down is made larger, so that it is helpful to prevent the drop and jounce of the FOUP 3.

### (In-Storage Transporting Operation)

Next, with reference to FIG. 2 to FIG. 4B, an explanation will be given on transferring the load in the storage related to this embodiment, that is, the operation of in-storage transporting (i.e., the transporting within the storage).

In FIG. 2 as well as FIG. 4A and FIG. 4B, the FOUP 3, which is loaded by the transporting carriage 2 and is put on one second putting surface 15a in the area P1, is transferred to another second putting surface 15a (shown by an area P2, in FIG. 2 as well as FIG. 4A and FIG. 4B) in the same stage. In this case, first, the putting portion 11 (which is shown by the broken line in FIG. 2), which has finished transporting the FOUP 3 onto the second putting surface 15a in an area P3, is moved to just under the second putting surface 15a in the area P1. At this occasion, the putting portion 11 is moved to an approximate center of the horizontal guide 17 by the horizontal driving portion 13, and after that, the putting portion 11 is moved to the predetermined vertical position along the vertical guide 18 by the vertical driving portion 14. This predetermined vertical position is below the second putting surface 15a in the area P1. After that, the putting portion 11, existing at the predetermined vertical position, is moved to the predetermined horizontal position (which is shown by the solid line in FIG. 2) along the horizontal guide 17 by the horizontal driving portion 13. As shown in FIG. 3A, this predetermined horizontal position is a position where the convex part 12 of the putting portion 11 exists on the lower side in the vertical direction of the concave part 6 of a FOUP 3.

The putting portion 11, which has been moved to the predetermined vertical position and horizontal position, is then moved upwards by the vertical driving portion 14. By moving upwards, the first putting surface 11a passes through the center of the second putting surface 15a. Then, as shown in FIG. 3B, the first putting surface 11a is raised above the second putting surface 15a. At this time, the concave part 5 and the convex part 16 are disengaged in the area P1. Then, in place of the second putting surface 15a, the FOUP 3 is supported on the first putting surface 11a, and the convex part 12 of the putting portion 11 and the concave part 6 of the FOUP 3 are engaged with each other. Thus the FOUP 3 is transferred from the second putting surface 15a to the first putting surface 11a.

The putting portion 11 on which the FOUP 3 has been transferred is moved to right above the second putting surface 15a in the area P2. At this occasion, the putting portion 11 is moved to the predetermined horizontal position in the horizontal one direction by the horizontal driving portion 13. The predetermined horizontal position is a position where the concave part 5 of the FOUP 3 exists on the upper side in the vertical direction of the convex part 16 of the second putting surface 15a in the area P2. The putting portion 11, which has been moved to the predetermined horizontal position, is moved downwards by the vertical driving portion 14. By moving downwards, the first putting surface 11a passes through the center of the second putting surface 15a in the area P2. Then, as shown in FIG. 3A, the first putting surface 11a is lowered below the second putting surface 15a. At this time, the convex part 12 and the concave part 6 in the area P2 are disengaged in the area P2. By this, the FOUP 3 is supported on the second putting surface 15a in place of the first putting surface 11a, and the concave part 5 of the FOUP 3 and the convex part 16 of the second putting surface 15a are engaged with each other. Thus the FOUP 3 is transferred from the first putting surface 11a to the second putting surface 15a in the area P2. For this reason, the operation of transferring the FOUP 3 from the area P1, which is set as a port, to the area P2 is completed. Incidentally, if the operation of transferring is performed in the inverse process, transferring from the area P2 to the area P1 is operated. Therefore, the above described operation of transferring through the port is also the operation for loading and unloading the FOUP 3 between the transporting carriage 2 and the stocker 10.

As described above, according to the stocker 10 in this embodiment, the stocker 10 extends in the vertical direction and the horizontal one direction, and the stocker 10 is constructed to be extremely thin, including the space needed for the thickness of one FOUP 3 and the movement of the horizontal driving portion 13 and the vertical driving portion 14, in the thickness direction. For this reason, into an even relatively small space along the rail 1, the stocker 10 can be disposed. The putting portion 11 which moves in the two-axis directions is not needed in the loading and unloading between the port and the transporting carriage 2, and the putting portion 11 does not interfere with the operation of loading and unloading. Thus it is possible to load and unload the FOUP 3 efficiently and it is also possible to perform the in-storage transportation efficiently, by use of a simple structure.

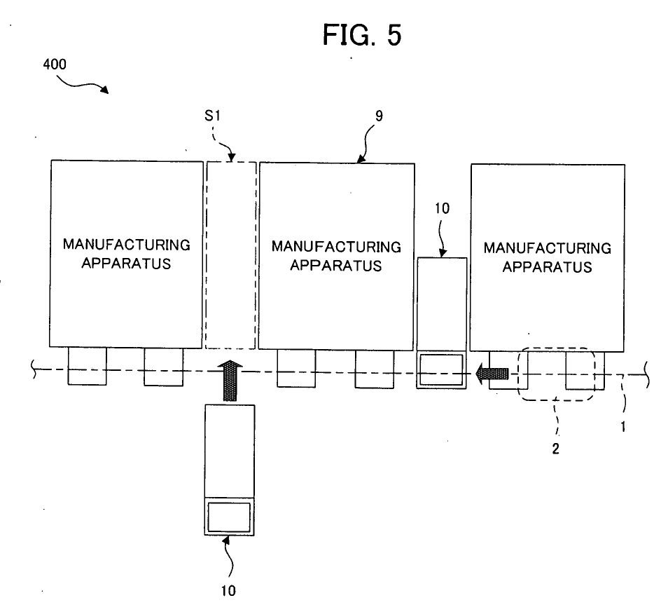

Next, with reference to FIG. 5, the arrangement of the storage is explained. FIG. 5 is a plan view showing a practical arrangement condition of the storage in the first embodiment.

As shown in FIG. 5, the storage is arranged in the space between the manufacturing apparatuses and the like, set along the track in a factory, such as a semiconductor manufacturing factory. The size of the stocker 10 in the thickness direction is designed to correspond to the space (or gap) between the manufacturing apparatuses 9. Between the manufacturing apparatuses 9, the space S1 for maintenance is reserved. By inserting the stocker 10 into the space S1, the space S1, which may be called as a wasted space except at the time of maintenance, is utilized effectively. The manufacturing apparatuses 9 and the stocker 10 arranged between these manufacturing apparatuses 9 are arranged in such a manner that the horizontal one direction, in which the putting portion is moved, perpendicularly intersects the rail 1.

Additionally, although the stocker 10 shown in FIG. 5 is arranged alone, the stocker 10 may be arranged in the form of the stocker set which consists of a plurality of stockers, in line with the space between manufacturing apparatuses.

### Second Embodiment

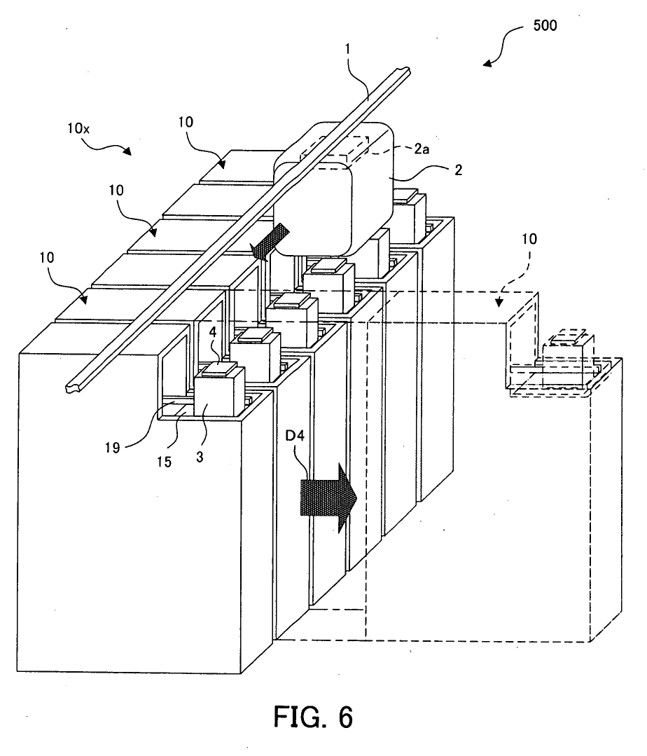

Next, as a second embodiment of the present invention, a storage set constructed by combining a plurality of storages in the first embodiment is explained with referring to FIG. 6. Here, FIG. 6 is a perspective view showing the external appearance of the transporting system including the storage set of this embodiment, whose general purpose is the same as that of FIG. 1. Incidentally, in the transporting system shown in FIG. 6, the same constituent elements as those in the transporting system 100 shown in FIG. 1 carry the same reference numerals and the explanations thereof are omitted.

In FIG. 6, a transporting system 500 is provided with the rail 1, the transporting carriage 2, and a plurality of stocker sets 10x. In the transporting system 500, the transporting carriage 2 is driven to thereby perform the transportation of the FOUP 3 on the rail 1 by a not-illustrated controller in the same manner as the transporting system 100 shown in FIG. 1.

The stocker set 10x has six stockers 10. Each stocker 10 is provided with an in-storage transporting apparatus 19 including the not-illustrated putting portion; and the plurality of racks 15, in the same manner as in the stocker 10 shown in FIG. 1. The in-storage transporting apparatus 19 moves the putting portion in the two-axis directions of the horizontal one direction and the vertical direction. Thus the in-storage transporting apparatus 19 transfers the FOUP 3 among the racks 15. One rack 15 located on the top stage of the racks 15 (i.e., the rack on which the FOUP 3 is put in FIG. 10) functions as a port for loading and unloading.

The six stockers 10 included in the stocker set 10x are arranged such that the racks 15 for unloading and loading are arranged in one line below the rail 1 and along the rail 1. Each stocker 10 is arranged such that the azimuth of the horizontal one direction in which the putting portion is moved perpendicularly intersects the azimuth of the rail 1.

### (Loading and Unloading Operation in the Storage Set)

The operation for loading and unloading between the transporting carriage 2 and the stocker set 10x in the second embodiment, will be simply explained.

In the FIG. 6, when each of the six stockers 10 in the stocker set 10x stores the different FOUP 3, the transporting carriage 2 reciprocates between (i) the narrow area where the rail 1 exists in correspondence with the stocker set 10x and (ii) the destination of each FOUP 3. Thus the different six types of FOUPs 3 can be loaded and unloaded. In this case, the FOUP 3 of the second stocker 10, which is arranged on the downstream side of the first stocker 10, can be unloaded by the transporting carriage 2, which has just finished the loading to the first stocker 10, which is arranged on the upstream side of the rail 1. Furthermore, when a plurality of transporting carriages 2 travel to this stocker set 10x, the six FOUPs 3 can be simultaneously loaded and unloaded at the six stockers 10.

As described above, according to the second embodiment, the storage set 10x, in which the total number of the stockers 10 is adjusted, can be appropriately arranged in a relatively small space or a large space along the rail 1. The stockers 10 constituting the stocker set 10x are arranged such that the ports in the stockers 10 are arranged in one line along the rail 1. For this reason, the operation for loading and unloading can be performed on any port by the transporting carriage 2 which travels on the rail 1, so that the transferring efficiency is extremely improved.

### Third Embodiment

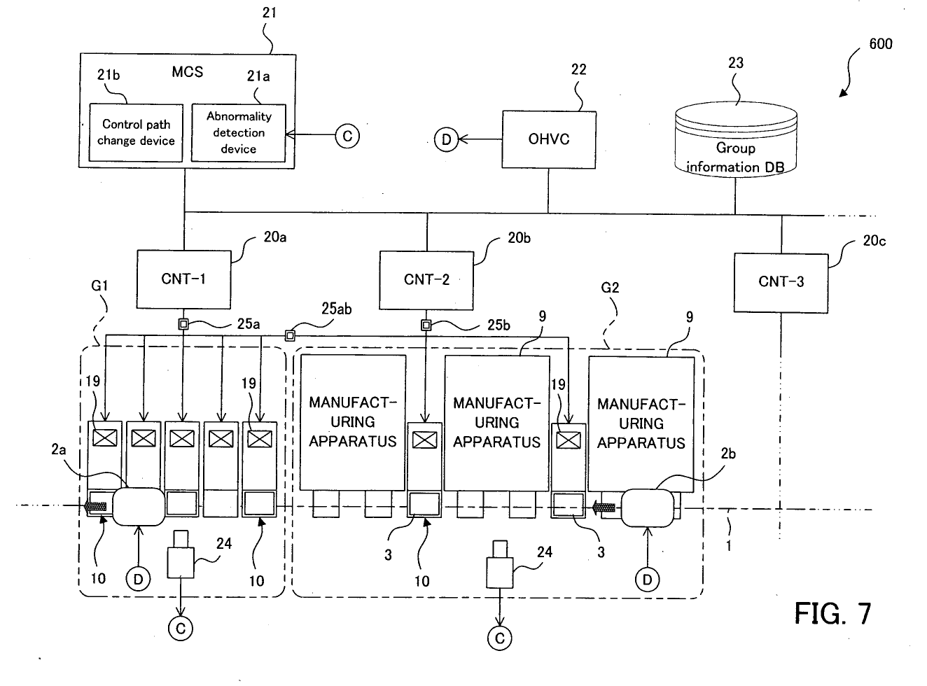

Next, an explanation will be given on a transporting system provided with a storing apparatus, which includes the storage in the first embodiment and the storage set in the second embodiment, as a third embodiment of the present invention, with reference to FIG. 7. FIG. 7 is a functional block diagram showing the structure of the transporting system in the third embodiment.

In FIG. 7, a transporting system 600 is provided with a plurality of controllers 20; a MCS (Material Control System) 21; an OHVC 22; and a group information database (DB) 23, which are connected to each other by a wired or wireless control line. In the transporting system 600, the plurality of stockers 10 or the like installed along the rail 1 are divided into a plurality of groups G1, G2, and so on, as a control unit. As shown in FIG. 7, the group G1 is provided with the stocker set 10x constructed by combining five stockers 10. The group G2 is provided with two stockers 10, each being disposed between two of the three manufacturing apparatus 9. Each of the stockers 10 is provided with a driving device. Each of the groups G1, G2, and so on is the control target of respective one of the controllers 20 and is assigned to at least one controller 20.

Each of the plurality of controllers 20 performs the control of loading and unloading, inventory management, rack management, or the like on the assigned group. Typically, each controller 20 is connected with the stockers 10 in the assigned group by a wired or wireless control line. Specifically, a first controller 20a to which the group G1 is assigned is connected with each of the in-storage transporting apparatuses 19 of the five stockers 10. A second controller 20b to which the group G2 is assigned is connected with each of the in-storage transporting apparatuses 19 of the two stockers 10.

In particular, in the embodiment, if any of the plurality of controllers 20 breaks down or goes out of order, another controller 20 performs complementary control, instead of the broken or out-of-order controller 20. As for the combination of the controllers which perform the complementary control, the first controller 20a for controlling the group G1 and the second controller 20b for controlling the group G2 make a pair. In this case, when the first controller 20a breaks down or goes out of order, the first controller 20a is stopped, and instead of the first controller 20a, the second controller 20b controls the group G1 and the group G2.

The MCS 21 is provided with an abnormality detection device 21a and a control path change device 21b and integrally controls each device or portion of the transporting system 600. The abnormality detection device 21a is provided with one monitoring device 24 in each group. The monitoring device 24 is placed along the rail 1 and monitors the FOUP 3, which is transported on the basis of a manufacturing schedule for semiconductor device manufacturing. On the basis of a monitoring result, the abnormality detection device 21a detects the failure or abnormality of the controller 20.

The control path change device 21b is one example of the “changing device” of the present invention. The control path change device 21b controls a plurality of changeover switches 25 on the basis of a detection result of the abnormality detection device 21a, to thereby change the control line to one for complementary control. The plurality of changeover switches 25 are provided with switches (e.g. changeover switches 25a and 25b), each being placed on the control line for connecting one controller 20 and the group controlled by the one controller 20; and a switch (e.g. changeover switch 25ab) placed on the control line for connecting the groups controlled by the plurality of controllers 20, which are combined in the complementary control.

Specifically, if the failure or abnormality of the first controller 20a is detected by the abnormality detection device 21a, the control path change device 21b turns off the changeover switch 25a, placed between the first controller 20a and the group G1, and turns on the changeover switch 25ab, located between the two groups G1 and G2 respectively controlled by the first and second controller 20a and 20b. The control of the changeover switches 25a and 25ab allows the control path change device 21b to disconnect the group G1 from the first controller 20a and to connect the group G1 to the second controller 20. By this connection, the initially set control line is changed to the control line for complementary control, and the complementary control of the first controller 20a is performed by the second controller 20b which is a paired controller of the first controller 20a.

The OHVC 22 controls the transporting carriage 2 to load and unload the FOUP 3 with the stockers 10 or the manufacturing apparatuses 9.

The group information DB 23 stores therein information about the stockers 10 which constitute each group, information about the controller 20 for controlling each group, information about the controllers 20 combined by the complementary control, and the like. On the basis of those information, the changeover switches 25 are controlled by the control path change device 21b.

### (Complementary Control Process)

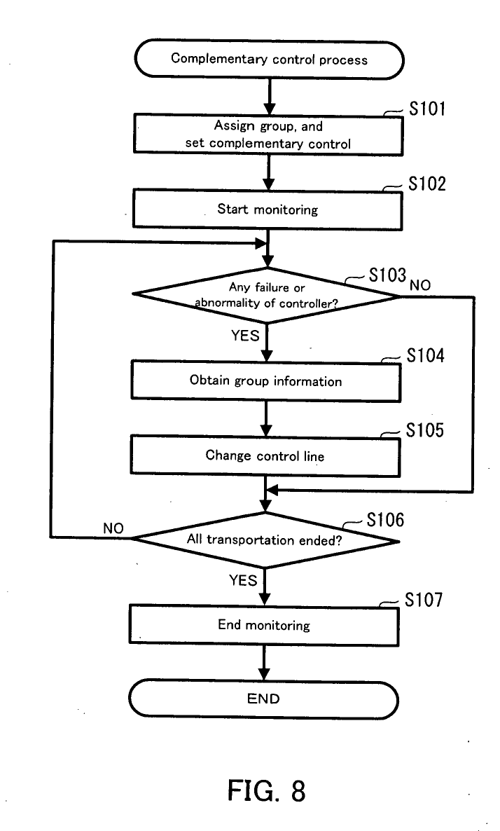

Next, a complementary control process of the transporting system in the third embodiment is explained with reference to FIG. 8. Here, FIG. 8 is a flowchart showing the complementary control process of the transporting system in the third embodiment.

In FIG. 8, firstly, the plurality of stockers 10 and the manufacturing apparatuses 9, installed along the rail 1 as the initial setting, are divided into the groups G1, G2, and so on, and the divided groups G1, G2, and so on are assigned to the plurality of controllers 20a, 20b, and so on, respectively, as control units. Moreover, the combination of the complementary control is set among the plurality of controllers 20 (step S101). The setting may be performed in a fixed manner to the transporting system or as the premise of the complementary control process. Alternatively, as in the embodiment, the setting may be performed in a variable manner or as occasion demands, as the initial setting in each opportunity of the process. All the information is stored in the group information DB 23. After the initial setting, when the transportation of the FOUP 3 is started as the actual operation of the transporting system 600, the monitoring is started by the abnormality detection device 21a (step S102).

When the monitoring is started, it is judged whether or not the failure or abnormality of any of the controllers 20 is detected, on the basis of the monitoring result (step S103). As a result of the judgment, if the failure or abnormality of any of the controllers 20 is not detected (the step S103: NO), it is judged whether or not all the transportation is ended (step S106).

On the other hand, if the abnormality of the first controller 20a is detected (the step S103: YES), the information about the group assigned to the first controller 20a (i.e. the group G1) and the information about the paired controller (i.e. the second controller 20b) combined by the complementary control are obtained from the group information DB 23 by the MCD 21 (step S104). Then, the control line is changed by the control path change device 21b on the basis of those information, by which the group G1, connected to the first controller 20a in the initial setting, is connected to the second controller 20b (step S105). By this connection, the first controller 20a is complementarily controlled.

Then, it is confirmed whether or not all the transportation is ended (step S106), and if it is not ended (the step S106: NO), the failure or abnormality of the controller 20 is judged again (the step S103). On the other hand, if all the transportation is ended, the monitoring is ended (step S107), and a series of contemporary control process is ended.

As described above, the plurality of controllers 20 are used to perform distributed control by the group unit and allow the complementary process. Thus, it is possible to efficiently use a hardware resource and improve economic efficiency while maintaining the high capacity utilization of the stocker set 10x or the transporting system 600 as a whole.

The present invention is not limited to the embodiments described above. The invention may be embodied in other specific forms without departing from the spirit or essential characteristics thereof. The present embodiments are therefore to be considered in all respects as illustrative and not restrictive, the scope of the invention being indicated by the appended claims rather than by the foregoing description and all changes which come within the meaning and range of equivalency of the claims are therefore intended to be embraced therein.

The entire disclosures of Japanese Patent Application No. 2008-075430 filed on Mar. 24, 2008 including the specification, claims, drawings and summary are incorporated herein by reference in their entireties.

What is claimed is:

1. A storing apparatus comprising a storage set installed along a track, the storage set being constructed by combining a plurality of storages in each of which loading and unloading of a load is performed with a transporting carriage for transporting the load on the track,
each of the plurality of storages comprising:
a driving device capable of reciprocating the load in a horizontal one direction and in a vertical direction; and
a rack having a plurality of rack portions at a plurality of stages in the vertical direction, each stage including one or a plurality of rack portions in the horizontal one direction, the rack portion capable of accommodating or putting thereon the load to be displaced by said driving device,
said storing apparatus comprising a plurality of controllers, which control the loading and unloading in respective groups, each group comprising at least one or a plurality of storages of the plurality of the storages, and which can perform complementary control with each other.

2. The storing apparatus according to claim 1, further comprising a changing device for changing a control path by the plurality of controllers to a control path for complementary control.

3. The storing apparatus according to claim 2, wherein if a failure or abnormality is detected in one of the plurality of controllers, said changing device performs the changing such that the complementary control of the one controller is performed by another of the plurality of controllers.

4. The storing apparatus according to claim 1, wherein said driving device comprises:
a putting portion having a first putting surface which can support the load from a bottom side of the load;
a horizontal driving portion capable of reciprocating the putting portion in the horizontal one direction; and
a vertical driving portion capable of reciprocating the putting portion in the vertical direction, and
said rack has second putting surfaces as the rack portions, one or a plurality of second putting surfaces being disposed at horizontal positions to which the horizontal driving portion can access, each second putting surface capable of transferring the load with the first putting surface.

5. A transporting system with a storage, comprising:
a storing apparatus comprising a storage set installed along a track, the storage set being constructed by combining a plurality of storages in each of which loading and unloading of a load is performed with a transporting carriage for transporting the load on the track, each of the plurality of storages comprising: a driving device capable of reciprocating the load in a horizontal one direction and in a vertical direction; and a rack having a plurality of rack portions at a plurality of stages in the vertical direction, each stage including one or a plurality of rack portions in the horizontal one direction, the rack portion capable of accommodating or putting thereon the load to be displaced by said driving device, said storing apparatus comprising a plurality of controllers, which control the loading and unloading in respective groups, each group comprising at least one or a plurality of storages of the plurality of the storages, and which can perform complementary control with each other;
the track; and
the transporting carriage.
